(19) United States
(12) Patent Application Publication
(10) Pub. No.: US 2013/0164556 A1
(43) Pub. Date: Jun. 27, 2013

(54) CIRCUIT BOARD WITH THERMALLY CONDUCTIVE LAYERS AND MANUFACTURING METHOD THEREFOR

(71) Applicants: SUNG-HSIANG YANG, Chu-Nan (TW); WEI-CHUN YEH, Chu-Nan (TW); CHENG-CHAO CHAO, Chu-Nan (TW)

(72) Inventors: SUNG-HSIANG YANG, Chu-Nan (TW); WEI-CHUN YEH, Chu-Nan (TW); CHENG-CHAO CHAO, Chu-Nan (TW)

(73) Assignee: FOXSEMICON INTEGRATED TECHNOLOGY, INC., Chu-Nan (TW)

(21) Appl. No.: 13/585,849

(22) Filed: Aug. 15, 2012

(30) Foreign Application Priority Data
Dec. 27, 2011 (TW) 100148751

(51) Int. Cl. B32B 15/04; B32B 15/01; H05K 1/09; B32B 3/10; H05K 3/06; B05D 5/12; B32B 15/08

(52) U.S. Cl. 428/626; 427/97.1; 428/672; 428/630; 428/633; 428/641; 216/17; 216/18; 174/257

(57) ABSTRACT

An exemplary method for manufacturing a circuit board includes, firstly, providing a substrate made of heat conductive, electrically insulative material. Then a copper layer is formed on the substrate. After that, nickel is plated on the copper layer to form a nickel layer. Finally, gold is and plated on the nickel layer to form a gold layer.

### BACKGROUND

1. Technical Field

The present disclosure relates to circuit boards and methods for manufacturing circuit boards, and more particularly, to a circuit board typically used to mount LEDs (light emitting diodes) thereon and a method for manufacturing such circuit board.

2. Description of Related Art

LEDs have many advantages, such as high luminosity, low operational voltage, low power consumption, compatibility with integrated circuits, easy driving, long term reliability, and environmental friendliness. Such advantages have promoted the widespread use of LEDs as a light source. Nowadays, LED lamps are commonly applied in lighting. However, the wavelength of the light emitted by such an LED lamp has red shift once the LED lamp overheats. Therefore the LED lamp needs to be maintained at a relatively cool temperature. Generally, a heat sink is fixed to a printed circuit board (PCB) on which one or more LEDs are mounted, for dissipating heat from the LEDs. However, a conventional PCB has low heat conductivity, resulting in a rather poor heat dissipation effect for the LED lamps.

What is needed, therefore, is a circuit board providing a high heat dissipation effect for associated components such as LED lamps, and a method for manufacturing such a circuit board.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

FIG. 1 is a flow chart showing a method for manufacturing a circuit board in accordance with an embodiment of the present disclosure.

FIG. 2 is a schematic, cross-sectional view of an exemplary circuit board manufactured by the method of FIG. 1.

### DETAILED DESCRIPTION

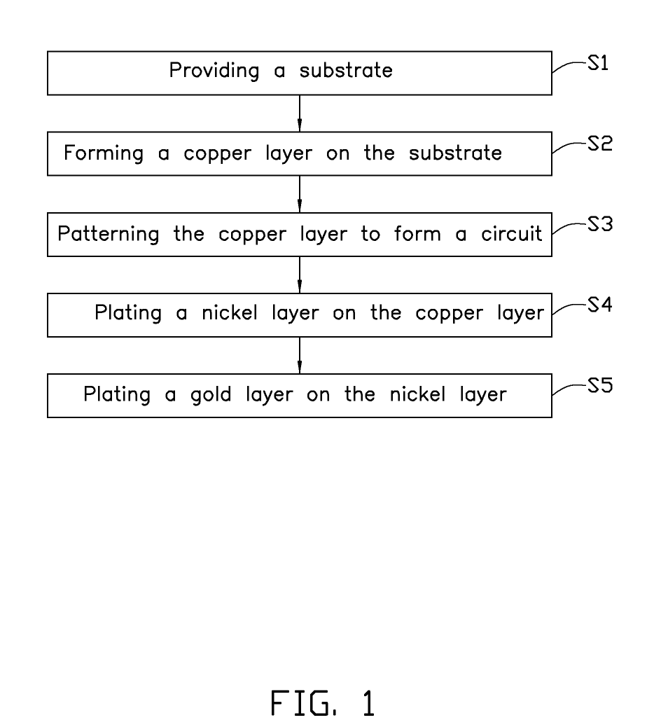

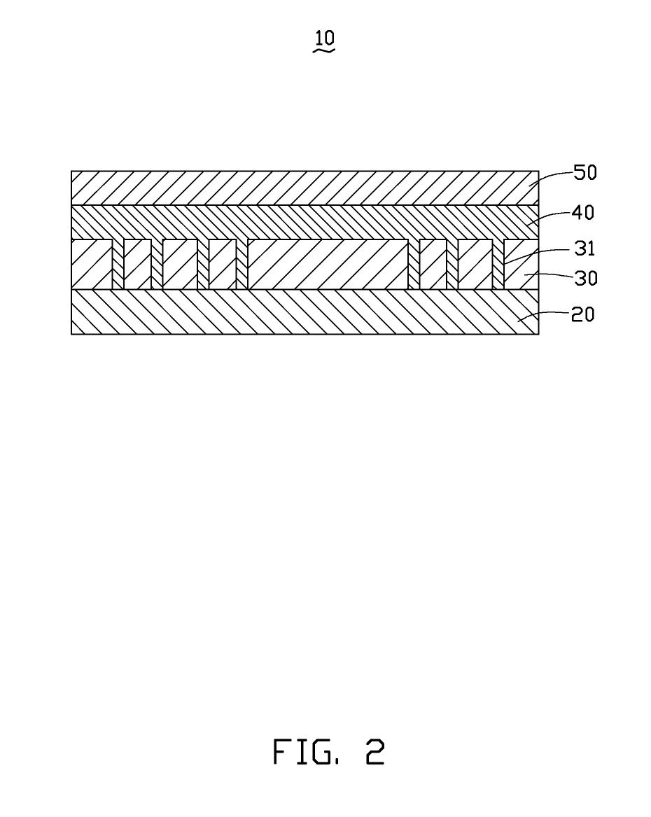

Referring to FIGS. 1-2, these show aspects of a method for manufacturing a circuit board 10 of an embodiment of the present disclosure.

In step S1, a flat substrate 20 is provided. The substrate 20 is made of electrically insulative, thermally conductive material such as rubber, ceramic, or silicon. In addition, the substrate 20 is not limited to the flat shape described and shown. The substrate 20 can have other shapes such as spherical, conical, or frustoconical, depending on the actual requirements.

In step S2, a copper layer 30 is formed on the substrate 20 by sputtering deposition under a temperature of about 373 K (Kelvin). The copper layer 30 covers a top surface of the substrate 20. Such plating of the copper layer 30 to the substrate 20 can increase a joint force therebetween, whereby the copper layer 30 does not easily separate from the substrate 20. A thickness of the copper layer 30 is larger than a thickness of the substrate 20.

In step S3, a circuit is formed in the copper layer 30 by patterning the copper layer 30, for example by etching. Thereby, a plurality of linear slots 31 is formed in the copper layer 30. Each linear slot 31 extends from a bottom face to a top face of the copper layer 30. Alternatively, the linear slots 31 can be formed in the copper layer 30 by other suitable methods.

In step S4, a nickel layer 40 is formed on the copper layer 30 by plating nickel material on the copper layer 30. The nickel layer 40 is also filled into the linear slots 31. Since nickel material has high corrosion resistance, the nickel layer 40 made of one or more nickel materials can prevent the copper layer 30 from corrosion (such as rusting) even after the circuit board 10 has been used for a long period. Thus, a circuit structure of the copper layer 30 is protected.

In step S5, a gold layer 50 is formed on the nickel layer 40 by plating gold on the nickel layer 40. Since gold has inactive chemical properties, the gold layer 50 can further prevent the circuit structure of the copper layer 30 from corrosion. That is, the circuit structure of the copper layer 30 is doubly protected. Due to the excellent metallic ductility of gold, the gold layer 50 can be made thin, and still have the advantages of anti-corrosion, good electrical conductivity, and good thermal conductivity.

Referring to FIG. 2, the circuit board 10 includes the substrate 20, the copper layer 30, the nickel layer 40 and the gold layer 50. Electronic components are set on the gold layer 50. Heat generated by the electronic components is transferred through the gold layer 50, the nickel layer 40 and the copper layer 30 to the substrate 20 in sequence. A thermal conductivity of pure copper is 401 W/[m*K] (watts per meter*Kelvin). A thermal conductivity of pure nickel is 90 W/[m*K]. A thermal conductivity of pure gold is 317 W/[m*K]. Therefore, the heat generated by the electronic components can be transferred from the gold layer 50 to the substrate 20 quickly.

In summary, the substrate 20 is made of material having good thermal conductivity, and the three metal layers 30, 40, 50 on the substrate 20 are all made of metallic materials having good thermal conductivity. Thus, a thermal conductivity of the circuit board 10 is improved. Furthermore, the substrate 20 can be made of transparent material such as glass or thermally conductive epoxy, for meeting special demands.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. A method for manufacturing a circuit board, comprising:
providing a substrate made of a heat conductive, electrically insulative material;
forming a copper layer on the substrate;
plating nickel on the copper layer to form a nickel layer; and
plating gold on the nickel layer to form a gold layer.

2. The method of claim 1, wherein the substrate is made of material selected from the group consisting of rubber, ceramic, silicon, glass and epoxy.

3. The method of claim 1, wherein the substrate is flat.

4. The method of claim 1, wherein a thickness of the copper layer is larger than a thickness of the substrate.

5. The method of claim 1, wherein the copper layer is formed on the substrate by sputtering deposition.

6. The method of claim 5, further comprising forming a circuit by patterning a plurality of slots in the copper layer.

7. The method of claim 6, wherein the patterning is performed by etching the copper layer.

8. The method of claim 6, wherein the nickel layer also fills the slots.

9. A circuit board, comprising:
a substrate made of thermally conductive, electrically insulative material;
a copper layer formed on the substrate;
a nickel layer formed on the copper layer; and
a gold layer formed on the nickel layer.

10. The circuit board of claim 9, wherein the substrate is made of material selected from the group consisting of rubber, ceramic, silicon, glass and epoxy.

11. The circuit board of claim 10, wherein the substrate is flat.

12. The circuit board of claim 11, wherein a plurality of slots are defined in the copper layer, and the nickel layer also fills the slots.

13. The circuit board of claim 11, wherein a thickness of the copper layer is larger than a thickness of the substrate.

14. A method for manufacturing a circuit board, comprising:
providing a flat substrate made of a heat conductive, electrically insulative material;
forming a copper layer on the substrate;
plating nickel on the copper layer to form a nickel layer; and
plating gold on the nickel layer to form a gold layer.

15. The method of claim 14, wherein a thickness of the copper layer is larger than a thickness of the substrate.

16. The method of claim 14, wherein the copper layer is formed on the substrate by sputtering deposition.

17. The method of claim 16, further comprising forming a circuit by patterning a plurality of slots in the copper layer.

18. The method of claim 17, wherein the patterning is performed by etching the copper layer.
